(19) United States
(12) Patent Application Publication
(10) Pub. No.: US 2004/0124828 A1
(43) Pub. Date: Jul. 1, 2004

(54) Device and method for continuously monitoring energy usage

(76) Inventor: Donald Craig Dunn, Colfax, CA (US)

Correspondence Address: NATIONAL IP RIGHTS CENTER, LLC, SCOTT J. FIELDS, ESQ., 550 TOWNSHIP LINE ROAD, SUITE 400, BLUE BELL, PA, 19422, US

(21) Appl. No.: 10/331,153

(22) Filed: Dec. 27, 2002

(51) Int. Cl. G01R 7/00

(52) U.S. Cl. 324/142

(57) ABSTRACT

A device for monitoring power usage comprising a first affixed to the power inlet of a facility for reading the amount of energy received at a facility; means for transmitting the amount of energy received at the facility to a control box; means associated with the control box for calculating the amount of the energy usage in a monetary unit; and display means for displaying the results.

### FIELD OF THE INVENTION

The present invention is directed to a system for monitoring power usage in a house, apartment, office or other facility. In particular, the present invention is directed to a device, system and method for calculating electrical power and for providing an accurate measurement of the power as it is being used in the U.S. dollars or other monetary unit.

### BACKGROUND OF THE INVENTION

The present invention is directed to a system for monitoring electrical power and providing the end user with a mathematically accurate measurement of energy as it is being continuously used in a specific monetary unit such as U.S. dollars. To date, there have been a number of systems for monitoring or measuring electricity in homes, apartments and offices. Most of these systems relate to the monitoring of electric power to be read by meter readers for purposes of billing. Meter Readers are employees of electric utilities who go door-to-door reading utility meters. A number or recent technologies have been developed for enabling the remote reading of electric power meters and the like.

U.S. Pat. No. 5,548,209 entitled “Solid State Electric Power Usage Meter and Method for Determining Power Usage”, for example, discloses a digital solid state electric power usage system by a load attached to an electric tower network. The meter has a current sensor coupled with each phase of an electric power network for sensing current in each phase, a voltage divider coupled to each phase of the power network for detecting the voltage level on each phase, a lock to digital converter coupled to the current sensors, and voltage dividers receiving signals from the current sensors related to the current in each phase that signals from the voltage dividers related to the voltage on each phase.

Typically, when most North Americans receive their monthly electric bills, the bill is generally presented in units of “kilowatt hours”. Some utility bills include charts and graphs and often discuss a daily usage rate in kilowatt hours and may provide monthly comparison information. The average untrained consumer has no conception of what the term “kilowatt hours” means or its association with the use of electricity or its relationship to the particular electric usage related to consumer electronics and utility devices such as a washing machine or dishwasher.

It is therefore virtually impossible for the average consumer to understand the relationship between kilowatt hours and the typical electric bill. While there have been a number of systems for measuring power, there is no prior art that provides this information and relates electric usage to easily understood monetary denominations such as dollars.

There has never been a system which illustrates the rate of electric power usage on a continuing basis and which provides the end user consumer with a continuous readout of that usage in monetary units such as U.S. dollars.

There is a long felt need for a small digital unit which converts electric power which is approximately the size of a digital thermostat, and which can be mounted in a home, office or apartment.

There is a further long felt need for a unit that can track and store past and present electric energy consumption and the usage habits of individuals using common monetary units such as dollars.

There is a long felt need for a device which will display the amount of energy that is being used and the costs associated with that usage in easily understood monetary denominations such as dollars. Unit costs could be displayed in terms of minutes, hours, days, weeks, months and years on a display.

The true nature and scope of the present invention is to be determined with reference to the following summary and claims.

### SUMMARY OF THE INVENTION

The present invention is directed to a system and method for measuring electrical power usage and converting that usage to common monetary values for use in homes, apartments and offices. The invention is designed to store all information from the date of installation and provide comparative information for any period and a plurality of statistics related to such usage. The present invention can compare electric energy usage patterns for a given hour, day, week, month or year or more. It further facilitates month-to month comparisons on a wide variety of statistical bases.

The invention preferably comprises two major components. The first component is a weatherproof energy measurement device that resides in, on, at or near the facility's main power supply inlet. This may be at an internal or external location with respect to the facility. The second component is an indoor control box that receives door digital computer component that receives the data from the measuring device via a radio, electronic, infrared or hard wire connection and then performs a multiplicity of functions including. The control box includes a display that illustrates on a continuing basis the cost of electric usage at the facility.

The system incorporates a microprocessor based control system which provides a series of calculations for the system and provides information on how far under or over a personal, targeted budget the user has gone. The invention, in a most preferred embodiment, will track usage in a variety of time denominations including weekly, monthly, yearly, etc., so that the user can program monetary usage plans.

It is anticipated that energy utilities could finance, install and offer rebates on the use of the present invention as they do with other energy conservation products. Local, state and federal tax incentives could similarly be provided for use of the present invention. The present invention further envisions additional devices that will show consumers how much money they've spent in preset units, as well as display current usage, displayed in preselected time increments. The present invention further envisions the use of an interface so that energy usage can be monitored remotely via the Internet or via wireless devices.

The wall unit of the present invention receives electrical usage signals which are obtained via the system transmitted to it via a radio, electric wire or infrared signal sent from the metering device that is located at the house, office or apartment's energy meter. This allows the placement of the control unit to be adjusted. This also facilitates installation of the system as no wiring to the control device which would be necessary. A hand-wired version could be used for new facility construction. The advantage of a permanent wired device is that there would be no need to replace batteries in the control unit. Several locations in a facility could be wired during construction to facilitate moving the invention when necessary.

In accordance with the present invention, a device for monitoring power usage at a facility is disclosed comprising: a mechanism affixed to the power inlet of a facility for reading the amount of energy received in at the facility; transmission means associated with the mechanism for transmitting a signal corresponding to the amount of energy received by the facility to a control system with tin the facility; means within the control box using pre-stored algorithms for calculating the amount of energy used by the facility and converting the amount of energy so used into a monetary denomination; and display means for displaying the results of the energy usage in a monetary unit.

### BRIEF DESCRIPTION OF THE FIGURES

FIG. 1 is a block diagram of the present invention.

FIGS. 2 and 2A are a schematic diagram and elevational views of the indoor control box of the present invention.

FIG. 3 is a block diagram of the meter reading component of the present invention.

FIGS. 4 and 5 are algorithmic flow charts which illustrate the means by which the present invention provides calculations.

### DETAILED DESCRIPTION

The present invention is described with reference to the enclosed Figures wherein the same numbers are used where applicable. In a broad embodiment, the present invention is directed to a system for monitoring power and for providing the end user with a mathematically accurate measurement of energy which can be displayed in monetary units via a wall based control unit.

The invention 10 comprises two principal components. The first comprises a weatherproof energy measuring and transmission device 11 that resides in, on, at or near the facilities' main power supply. For the purposes of this disclosure, the term “facility” refers to a house, office, apartment or other building having its own separate electric power meter. The second component is an indoor digital computer based control unit 12 that receives the data from the measuring device 11 via a radio, electronic, infrared or hard wire connection and that performs all of the functions to be described in detail below.

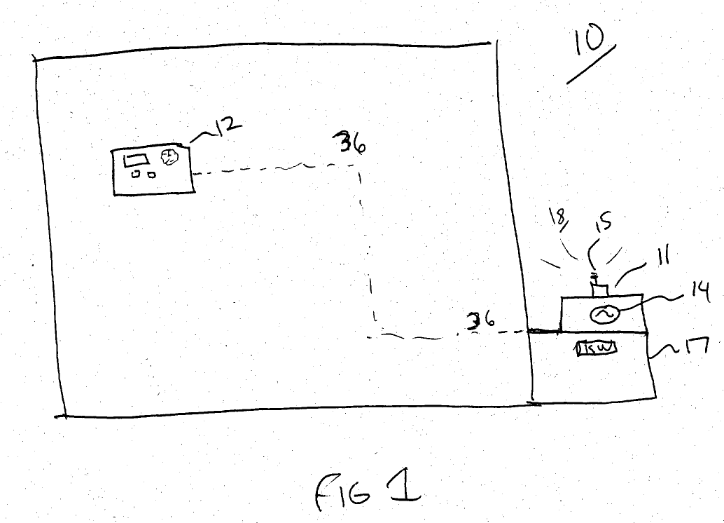

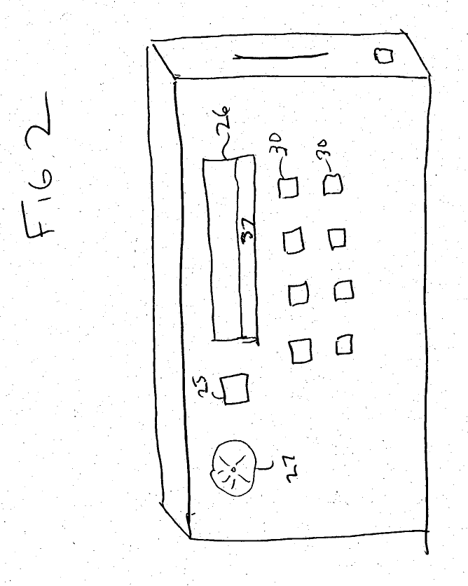

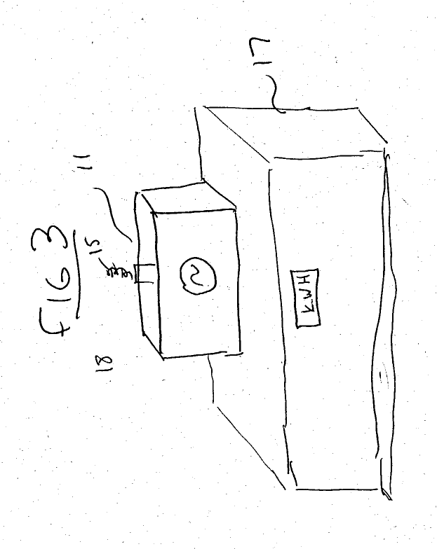

Referring to FIGS. 1 to 3, the present invention is shown in detail. As shown, the invention comprises a first metering unit 11 which is associated with the power input location 17. This unit 11 incorporates an ammeter or power meter 14 which takes a direct power reading of AC electric power of the as it enters the facility. This unit further contains an infrared or wire or radio transmitter 15 for transmitting a signal to the control box 12. This signal comprises an analog or digital signal representative of the direct power entering the facility in “kilowatt hours”.

The second component is control box or unit 12 which is affixed to a fixed location in the house, apartment, office, or facility. As noted, the control box 12 may be in direct electrical communication with the metering unit 11 via a wire 36. Alternatively, the electrical communication may be by means of infrared, radio or microwave communication 18. A hard-wired version could be used in the new facility construction, and may provide the advantage of not requiring replacement batteries. Several locations in the facility could be wired during construction to facilitate moving the invention when necessary. The invention could also utilize a rechargeable battery 19.

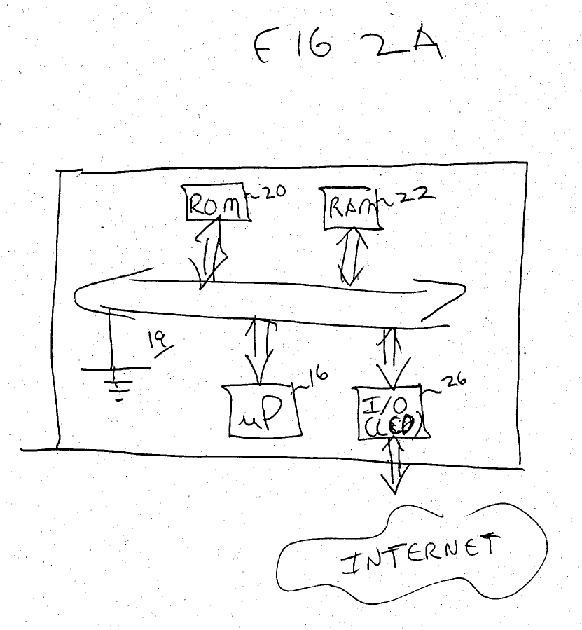

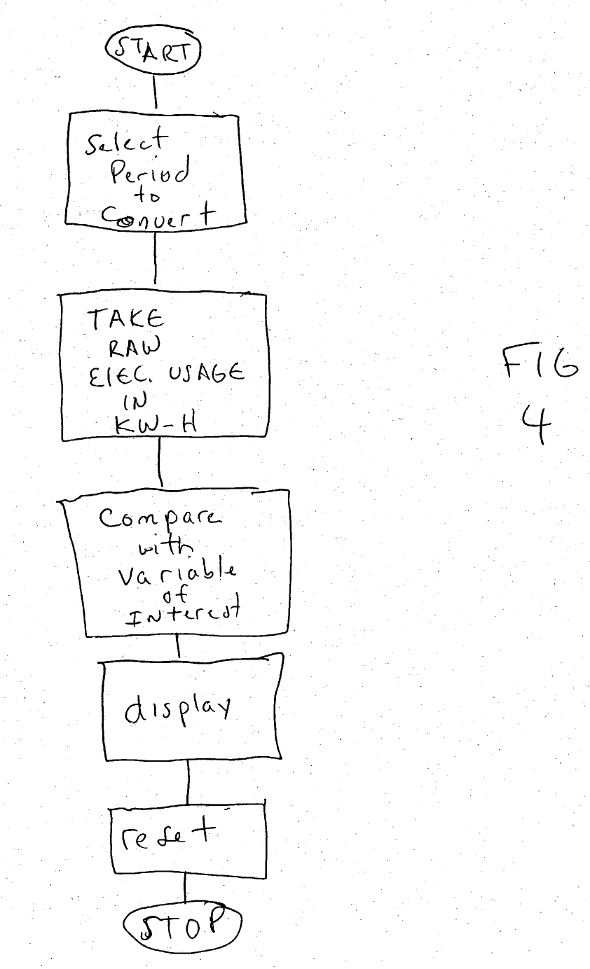

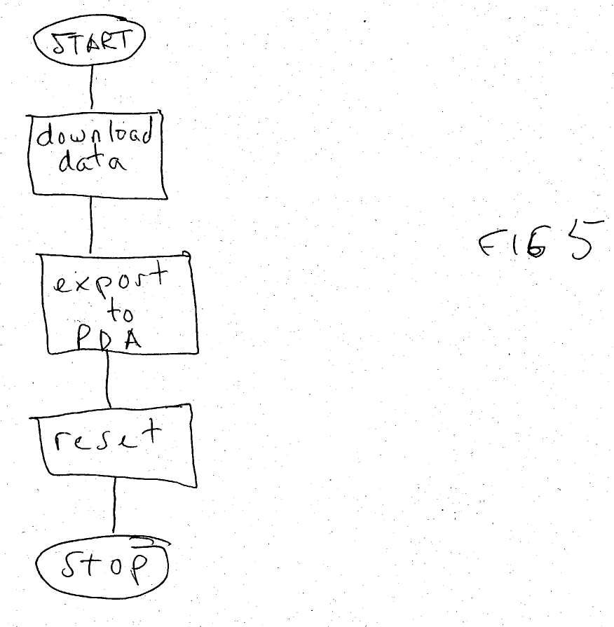

As noted, the meter unit 11 provides an accurate continuous signal representative of the amount of electricity in kilowatt hours which is being consumed by the facility. This signal is then sent to the control box 12. As shown in FIG. 2A, the control box 12 preferably comprises a number of components. The unit has a power pack 19 including charger and is powered by battery power or the direct AC signal of the facility. It further has a small microprocessor 16 with a read only memory ROM 20 and a RAM 22. The ROM 20 stores a series of software algorithms 24 set forth in FIGS. 4 and 5 which facilitate the conversion of the power signal received from the meter reading box from kilowatt hours into a running dollar or other monetary figures and which facilitate the calculation of additional comparative information and statistics.

The control box 12 allows the display to be completely movable so that the usage information is displayed wherever it is best at that time. The running dollar figure is then displayed on LCD or LED display 26 in real time. At the end of each month or billing cycle, the system 12 can be reset via a reset button 25 in order to provide a zero balance at the beginning of a given month.

It is to be appreciated that the prevent invention can further be configured to provide an alarm signal 27 in the event that the rate of electrical usage exceeds a preselected limit. In this way, the owner of the system can be alerted if high electrical usage and prompt reasonable steps can be taken to control electrical usage. The present invention further contains a system comparing electrical usage with earlier months as discussed below.

The present invention stores all usage information from the date of installation within RAM 22. A series of programming and control buttons 30 on the side of control unit 12, permit the system to be set and programmed. These buttons facilitate the presentment of continuous monetary readout 32, the readout in days, months or years 34 and the analysis of usage by days of the week. This programming allows the system to generate reports, and to provide detailed comparison to usages over any period of an hour, day, week, month or year. This feature of the present invention further includes a programmable querying feature 37 which allows for information to searched and displayed in LED readout 26. As shown in FIG. 5, additional algorithms are provided to facilitate the downloading of data via the Internet, PDA or wireless device.

The present invention tracks savings in all time monetary denominations weekly. The invention provides and indicates when a substantial cutback involving electric usage may be needed. Power companies could finance, install and offer rebates on the invention as they do with other energy conservation projects.

The present invention has been described with reference to the attached, preferred embodiment. It is to be appreciated that other embodiments fulfill the spirit and scope of the invention and that the true nature of the invention is to be determined with reference to the attached claims.

1. A device for monitoring power usage in a facility comprising:
a metering mechanism affixed to the power inlet of a facility home for reading the amount of energy received in a location
means associated with the metering mechanism for transmitting the amount of energy in the location to a control means;
said control means including means for calculating the amount of the energy usage in a standard of monetary measurement; and
display means for displaying the monetary measurement.

2. The device of claim 1 wherein the display means is an LED readout.

3. The device of claim 1 wherein the display comprises an LCD readout.

4. The device of claim 1 wherein said transmission means comprises an infrared signal.

5. The device of claim 1 wherein said transmission means comprises a radio transmitter

6. A device for monitoring power usage at a facility comprising:
a mechanism affixed to the power inlet of a facility for reading the amount of energy received in at the facility;
transmission means associated with the mechanism for transmitting a signal corresponding to the amount of energy received by the facility to a control system with tin the facility;
means within the control box using prestored algorithms for calculating the amount of energy used by the facility and converting the amount of energy so used into a monetary denomination; and
LCD display means for displaying the results of the energy usage in a monetary denomination.
